(19) United States
(12) Patent Application Publication
(10) Pub. No.: US 2025/0169251 A1
(43) Pub. Date: May 22, 2025

(54) LED WITH METAL REFLECTOR

(71) Applicant: Lumileds LLC, San Jose, CA (US)

(72) Inventors: Antonio Lopez-Julia, Vaals (NL); Konstantin Andreas Engeter, Singapore (SG)

(73) Assignee: Lumileds LLC, San Jose, CA (US)

(21) Appl. No.: 18/514,956

(22) Filed: Nov. 20, 2023

(51) Int. Cl. H01L 33/60; H01L 33/00; H01L 33/10; H01L 33/42

(52) U.S. Cl. CPC H10H 20/856; H10H 20/81; H10H 20/814; H10H 20/833

(57) ABSTRACT

Methods and devices including a die with a plurality of metal reflectors and/or a distributed bragg reflector (DBR) may improve optical efficiency and/or reflectivity of the system. The metal reflectors may be highly reflective and cover most of the die area including at least most of the n-contact areas. The DBR may also cover most of the die areas. Reflectivity may be improved as a result of one or both of these elements. Additionally, a transparent conductive oxide layer may cover the n-contact areas to improve current spreading.

### FIELD OF THE INVENTION

The invention relates generally to light emitting devices, particularly LEDs with a highly reflective metal reflector.

### BACKGROUND

The automotive and general illumination industry has witnessed remarkable advancements in technology, with one breakthrough being the invention of Light-Emitting Diodes (LEDs). This innovation has transformed the way we perceive and experience automotive lighting and general illumination, offering improved efficiency, durability, and versatility. Developed as a response to the limitations of traditional light source, automotive LEDs have become a staple feature in modern vehicles, providing enhanced safety, aesthetics, and functionality.

In the world of automotive lighting and general illumination, the pursuit of increased luminous flux has been a constant endeavor. Luminous flux, a measure of the total amount of visible light emitted by a light source, directly influences the practical usefulness of LEDs.

The reflectivity of dies in LEDs are functions of many things, including the size of the contact region at the n Vias and/or e Vias. The geometry of such dies and the size of their openings influence the size of the reflective elements that are incorporated within them. Reducing the size of such openings and/or otherwise adjusting the geometry of the layers in the dies can allow an increase of the reflective elements and a decrease in the size of the absorptive or less reflective elements. Such adjustments may increase the overall reflectivity and optical efficiency of the system.

### SUMMARY

Embodiments of the invention introduces a novel approach to increase luminous flux of LEDs over conventional structures. Compatible with chip scale package (CSP) architectures, embodiments of the invention include a die structure featuring a highly reflective metal reflector that covers most of the die area including the mesa-bottom regions (n-contact areas). The reflectivity is further enhanced with the incorporation of a DBR that further extends over most of the die areas (i.e. emitting and not emitting regions).

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6 schematically illustrates an example display (e.g., AR/VR/MR) system.

FIG. 7 shows a cross section of a die with metal reflectors spaced apart from each other and covering the n-side and much of the p-side of the die, according to embodiments of the invention.

FIG. 8 shows a cross section of a die with metal reflectors spaced apart from each other and covering the n-side and much of the p-side of the die, as well as a transparent conductive oxide layer that covers the entire n-side of the die, according to embodiments of the invention.

FIGS. 9a-9f shows plan views of different layers of the die according to embodiments of the invention.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries. The term “vertical” refers to a direction parallel to the force of the earth's gravity. The term “horizontal” refers to a direction perpendicular to “vertical.” The term “on” means to be disposed to overlap (e.g., vertically) and/or to be directly in contact with.

FIG. 1 shows an example of an individual pcLED 100 comprising a light emitting semiconductor diode (LED) structure 102 disposed on a substrate 104, and a phosphor layer 106 (also referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material, or be or comprise a sintered ceramic phosphor plate.

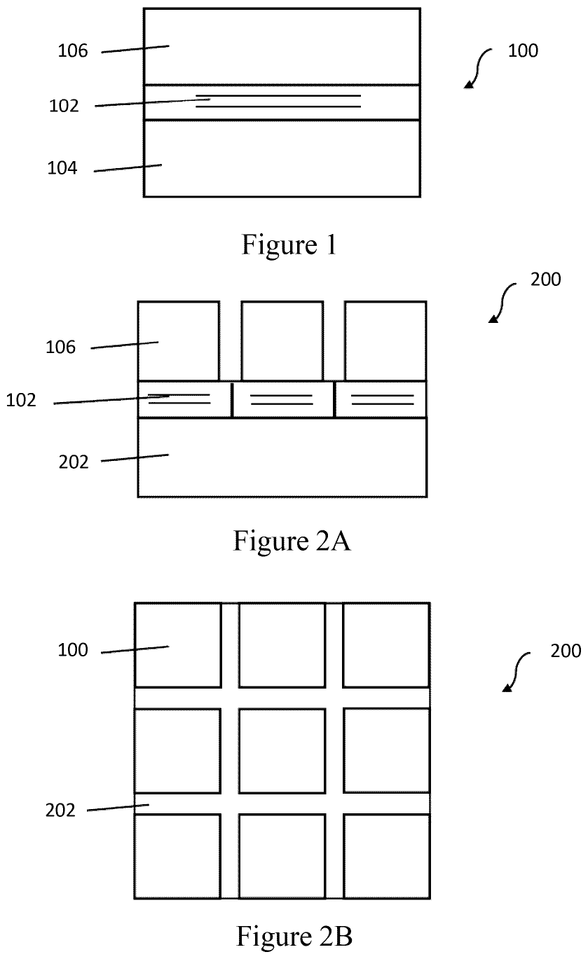

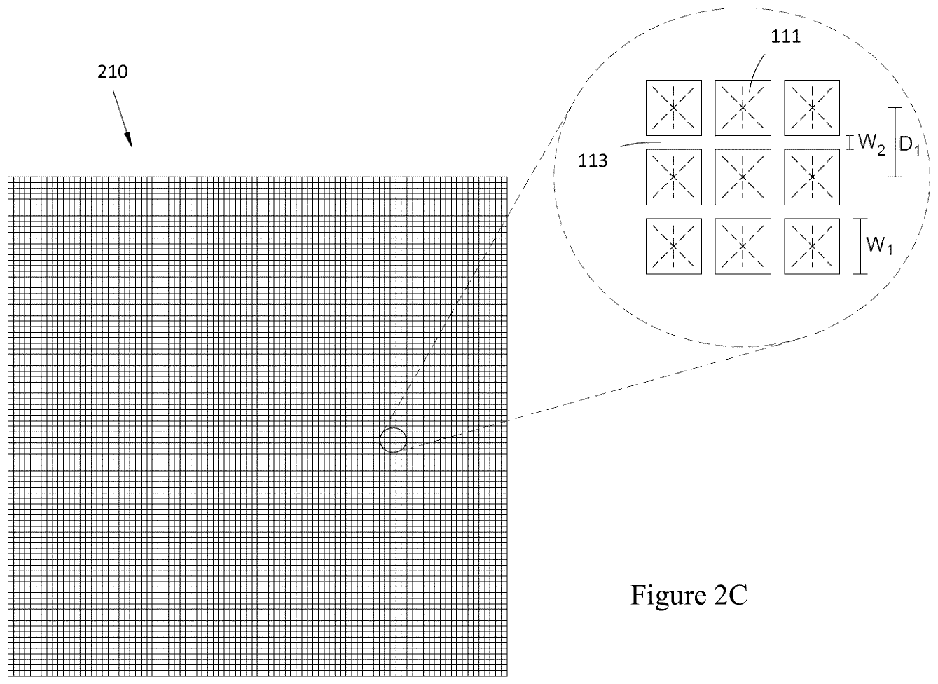

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from individual mechanically separate pcLEDs arranged on a substrate. Substrate 202 may optionally comprise CMOS circuitry for driving the LED and may be formed from any suitable materials.

Although FIGS. 2A-2B show a three-by-three array of nine pcLEDs, such arrays may include for example tens, hundreds, or thousands of LEDs. Individual LEDs may have widths (e.g., side lengths) in the plane of the array of, for example, less than or equal to 1 millimeter (mm), less than or equal to 500 microns, less than or equal to 100 microns, or less than or equal to 50 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W1 are arranged as a square matrix with neighboring LEDs or pcLEDs having a center-to-center distances D1 and separated by lanes 113 having a width W2. W1 may be, for example, less than or equal to 1 millimeter (mm), less than or equal to 500 microns, less than or equal to 100 microns, less than or equal to 50 microns, or less than or equal to 10 microns. W2 may be, for example, hundreds of microns, less than or equal to 100 microns, less than or equal to 50 microns, less than or equal to 10 microns, or less than or equal to 5 microns. D1=W1+W2.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs having dimensions in the plane of the array (e.g., side lengths) of less than or equal to about 50 microns are typically referred to as microLEDs, and an array of such microLEDs may be referred to as a microLED array.

Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated from each other by trenches and/or insulating material, but the electrically isolated segments remain physically connected to each other by portions of the semiconductor structure.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

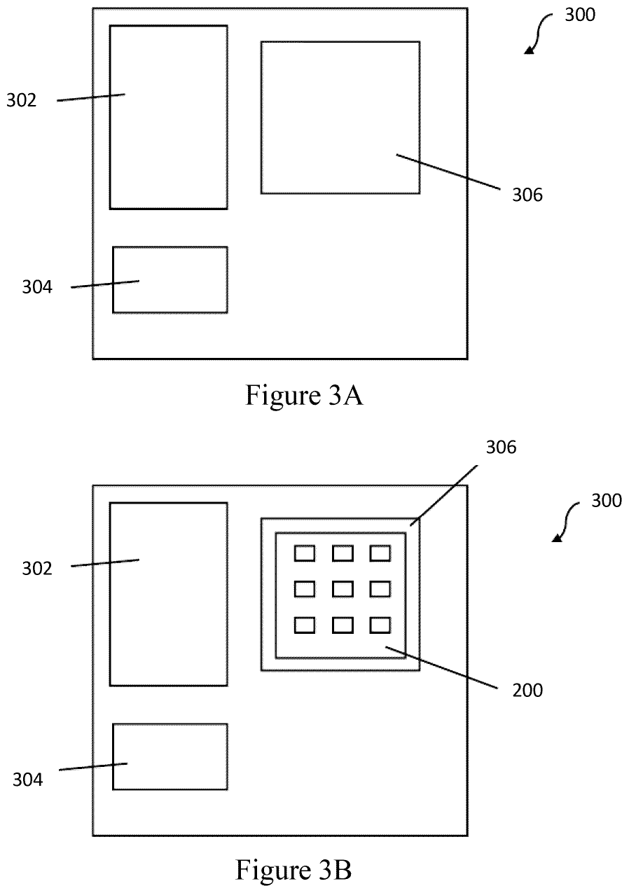

As shown in FIGS. 3A-3B, an LED or pcLED array 200 may be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

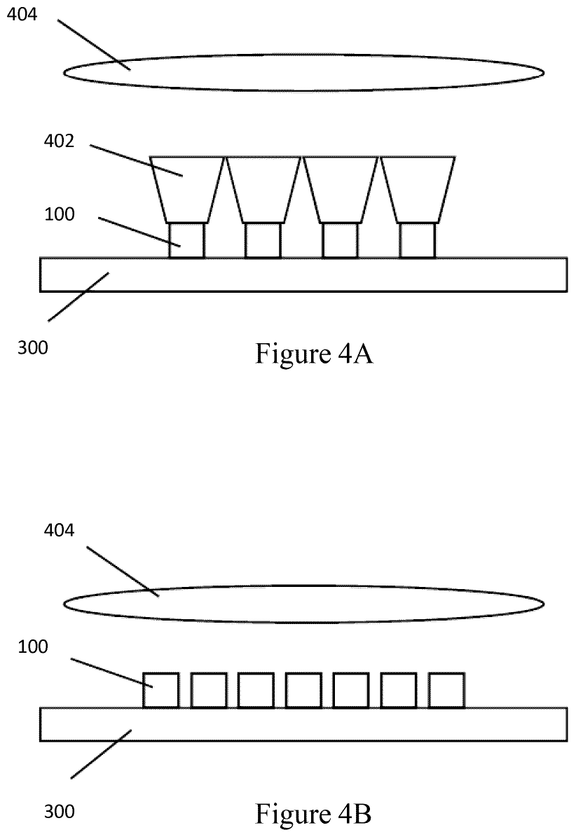

Individual LEDs or pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distribution. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), VR, and AR applications such as those described below.

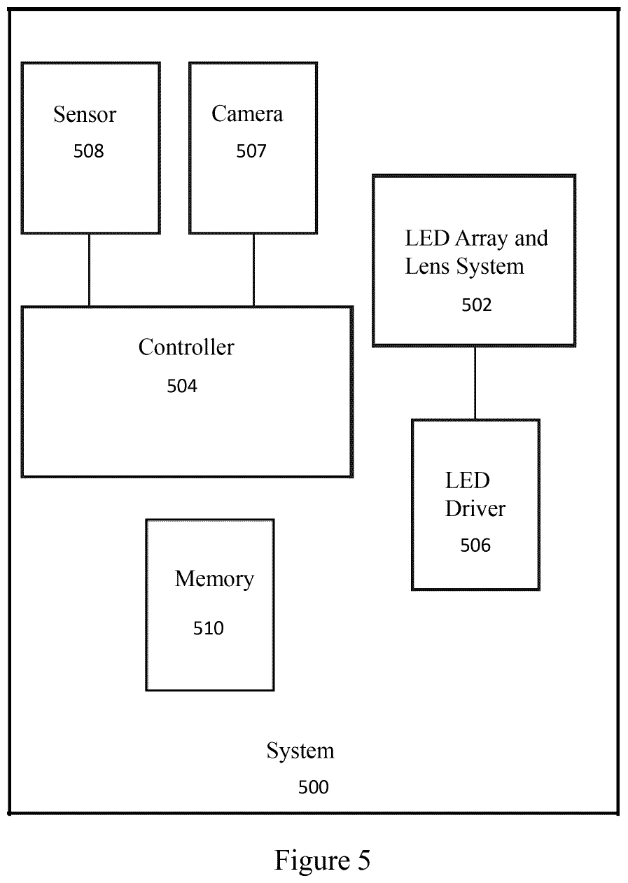

FIG. 5 schematically illustrates an example camera flash system 500 comprising an LED or pcLED array and lens system 502, which may be or comprise an adaptive lighting system as described above in which LEDs or pcLEDs in the array may be individually operable. In operation of the camera flash system, illumination from some or all of the LEDs or pcLEDs in array and lens system 502 may be adjusted-deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

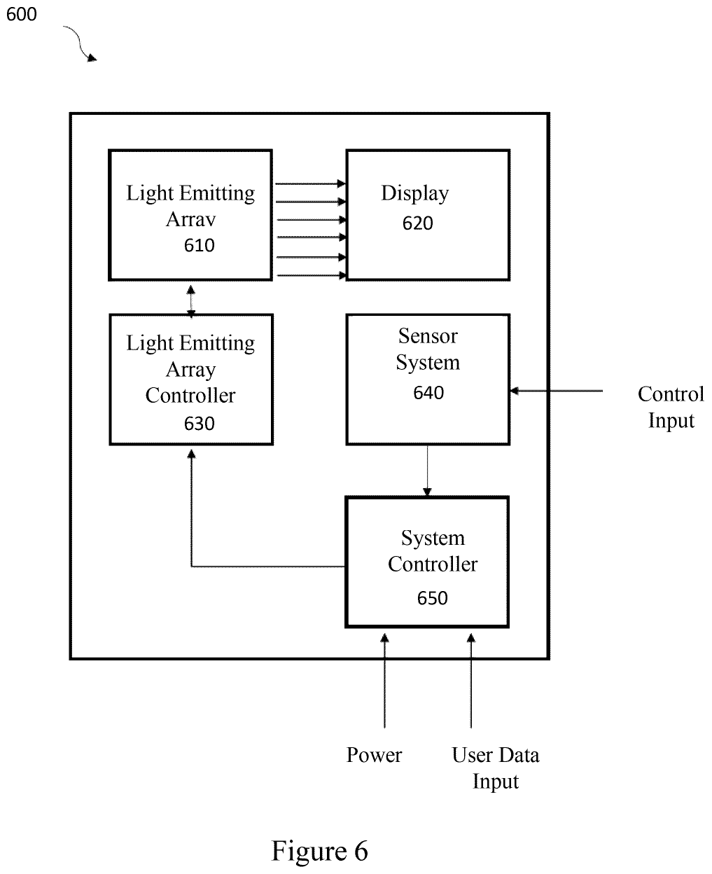

FIG. 6 schematically illustrates an example display (e.g., AR/VR/MR) system 600 that includes an array 610 of individually operable LEDs or pcLEDs, a display 620, a light emitting array controller 630, a sensor system 640, and a system controller 650. Array 610 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Array 610 can be used to project light in graphical or object patterns that can support AR/VR/MR systems

Control input is provided to the sensor system 640, while power and user data input is provided to the system controller 650. In some embodiments modules included in system 600 can be compactly arranged in a single structure, or one or more elements can be separately mounted and connected via wireless or wired communication. For example, array 610, display 620, and sensor system 640 can be mounted on a headset or glasses, with the light emitting array controller and/or system controller 650 separately mounted.

System 600 can incorporate a wide range of optics (not shown) to couple light emitted by array 610 into display 620. Any suitable optics may be used for this purpose.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

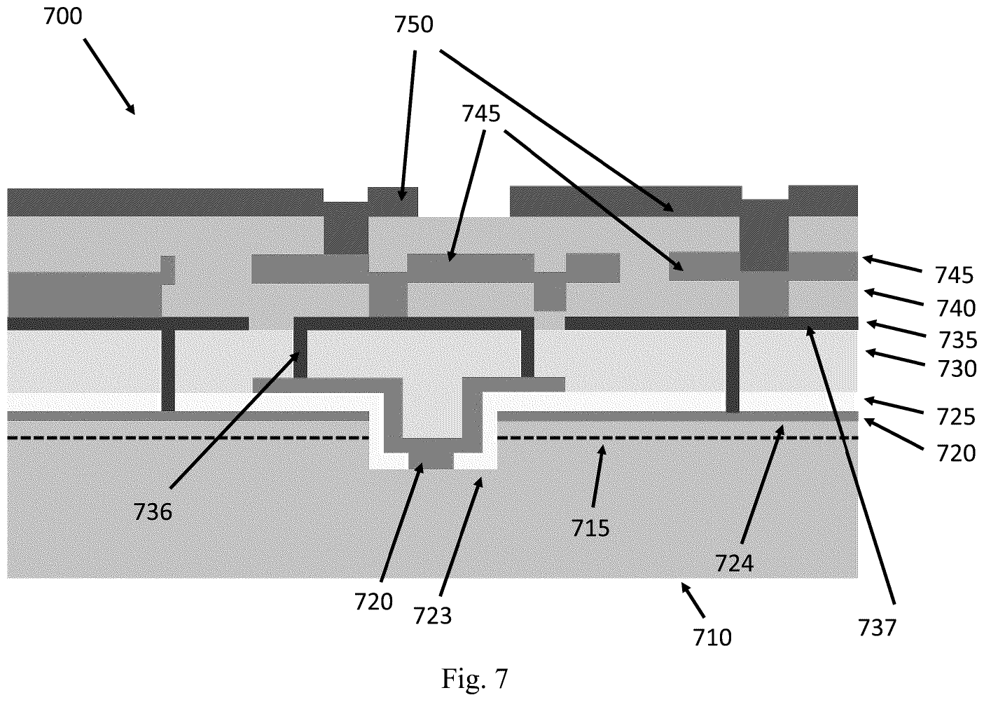

FIG. 7 depicts a light emitting device according to embodiments of the invention. The light emitting device includes a semiconductor structure 710 with an active region 715 that may emit light, e.g., visible light, e.g., blue light. The semiconductor structure may be or include p-doped semiconductor material stacked with an n-doped semiconductor material with the active region in between. The semiconductor structure may include GaN, and include a p surface 724 (of the p-doped semiconductor) sitting on top of a mesa and extending in a horizontal direction and an n surface 723 (a surface of the n-doped semiconductor material) below the mesa also extending in the horizontal direction (i.e., the n surface may comprise the entire mesa bottom region). The p surface may be disposed vertically higher than the n surface. A p-side transparent conductive oxide (TCO) 721 directly contacts the p surface of the semiconductor structure. The TCOs referred to in this specification may for example be or include indium tin oxide (ITO).

An n-side transparent conductive oxide (TCO) 720 sits at the n-side of the semiconductor structure (which is indicated by the depression in the semiconductor structure shown in FIG. 7). The n-side TCO may partially overlap the p-side TCO in the vertical direction, although this is not a requirement. The n-side TCO directly contacts the n surface of the semiconductor structure to spread current at the n-side. It can spread current laterally, making a smaller contact area to the n-side. The n-side TCO in the stack that provides current to the n surface improves reflectivity compared to if a metal were used to make an ohmic contact at that location. Here, the n-side TCO forms the ohmic contact at the n surface. The n-side TCO may be or include a same material as the p-side TCO, although this is not a requirement and the n-side TCO may be or include a different material as the p-side TCO.

Alternatively, it is also possible for adhesion reasons to have a very thin layer of dielectric between the TCO and the contacting metal. In any case, the smaller contacting area is beneficial, because it increases the size that the DBR 730 can have, which increases the reflectivity of the die. This DBR 730 works in conjunction with the plurality of metal reflectors 735 to prevent light leakage in the die. The DBR may be a dielectric layer stack alternating between low and high RI dielectric layers This DBR stack may be optimized to reflect the color of light emitted by the semiconductor structure, e.g., blue light,

The DBR may be disposed in between the n-side TCO and the metal reflectors to be in direct contact with both. The DBR may be disposed above (e.g, overlapping with in a vertical direction) a majority of or all of the n surface as well as a majority of the p surface. That is, the DBR may overlap the entire n surface. Above the region of the n surface, the DBR may extend vertically below the p surface.

The metal reflectors may be referred to as a segmented structure or a plurality of structures (e.g., first and/or second metal layers) that are physically spaced apart and/or electrically isolated from each other. For example, the metal reflectors may comprise at least a first metal reflector disposed above the entire n surface and partially over the p surface and a second metal reflector disposed entirely above the p surface. That is, the first metal reflector may overlap the entire n surface. The majority of the metal reflectors, by volume and/or area, may be disposed on a single layer. Each of the metal reflectors may have their largest areas disposed on a same layer as each other, e.g., extending in a same direction as each other, e.g., in a horizontal direction. In order for the metal reflectors to conduct current to their respective TCOs, they may have portions extending down vias in the DBR to directly contact the TCOs; these portions may extend perpendicular to one of the directions that the largest areas extend in, e.g., these portions may extend in the vertical direction. The metal reflectors, particularly first metal reflector, may not extend down below the p surface, e.g., they may not extend below the p-side TCO. The first metal reflector may not extend below the n-side TCO, but may directly contact its surface in at least two regions, each of which is above the p surface. The first metal reflector may not directly contact the n-side TCO above the n surface, although this is not a requirement. Because the first metal reflector does not extend down below the p surface, and because the contact region with the TCO is above the p surface in a vertical direction, light interaction is minimized so that optical efficiency of the die is increased. The second metal reflector disposed entirely over the p-side may extend below the n-side TCO and through the first insulating layer 725. The first insulating layer may include an oxide, such as SiO₂. The first insulating layer may be a stepped structure extending from above the p surface down to be in direct contact with the n surface. The first metal reflector may have a topmost planar surface that is aligned with a topmost planar surface of the second metal reflector.

The metal reflectors may each be in direct physical and electrical contact with respective bonding structures 745, which may be in direct contact physical and electrical contact with respective electrical contacts 750. The bonding structures may not be in direct physical nor electrical contact with each other, and the electrical contacts may not be in direct physical nor electrical contact with each other. The bonding structures may be disposed in second insulating layers 740, which may be or include a same or different material as the first insulating layer, and/or have a same refractive index as the first insulating layer. The bonding structure may include one or more different materials from the metal reflector and the electrical contact, and the electrical contact may include one or more different materials from the metal reflector (e.g., they may consist of different materials). The bonding structure and/or the electrical contact may include a metal, e.g., a non-silver metal. For example, the metal reflector may have a higher reflectivity than the bonding structure, and/or the bonding structure may have a higher conductivity than the metal reflector. That is, the metal reflectors may be highly reflective and be or include a material such as silver (e.g., the metal reflectors may consist of the same material or materials as each other, such as one metal).

Although this figure shows just one contact region of the n-side TCO with the n surface, a die according to embodiments of the invention may of course have multiple contact regions. For example, a die may have one or more n-side TCOs spaced apart from each other, one or more p-side TCOs spaced apart from each other, one or more bonding layers spaced apart from each other, and one or more metal reflectors spaced apart from each other. In one example, the die may have a single continuous p-side TCO that is in direct contact with one or more second metal reflectors, and a plurality of n-side TCOs each in direct contact with one or more first metal reflectors. That is, each of the n-side TCO and p-side TCO may be in direct contact with, respectively, multiple metal reflectors or a single metal reflector. Each of the one or more n-side TCOs may contact the n surfaces with total contact areas smaller than an entire area of the respective n-side TCO. An n-side TCO may directly contact the n surfaces at multiple contact areas spaced apart from and discontinuous with each other.

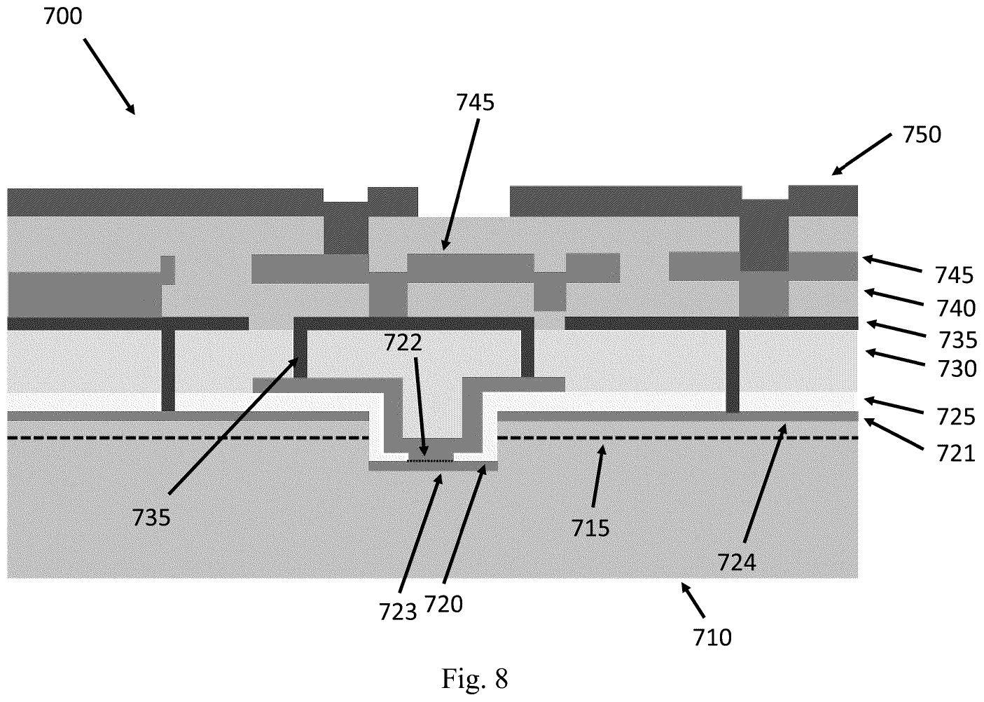

FIG. 8 depicts a light emitting device according to embodiments of the invention. In this die the n-side TCO 720 can be described as two regions separated by an imaginary line 722. The bottom region of the n-side TCO includes a planar region (i.e., a region with two flat surfaces extending parallel to each other in a lengthwise direction) that covers a majority of or an entirety of the n surface 723 (an entirety of the n surface including the entire length between two adjacent sidewalls of adjacent mesas, as shown in the figure). This advantageously increases the current spreading area of the n side TCO. The first insulating layer 725 may not extend down to the n surface extending in the horizontal direction, although it may be disposed on part of the sidewalls of the mesas atop of which sits the p surface 724. The top region of the n-side TCO vertically above the imaginary line includes the rest of the n-side TCO, which may be a stepped structure directly contacting the first metal reflector 735. The bottom region and top region of the n-side TCO may be deposited in separate steps. For example, the bottom region may be deposited in a same step as the p-side TCO 721. In any case, the bottom region and top region of the n-side TCO may form a monolithic, continuous structure.

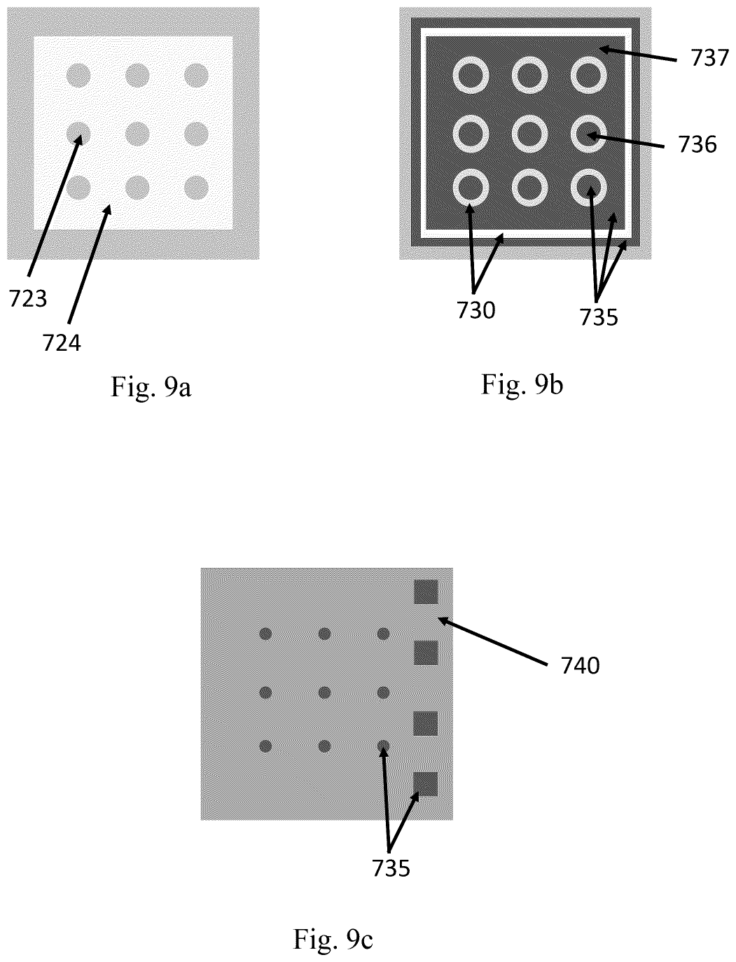

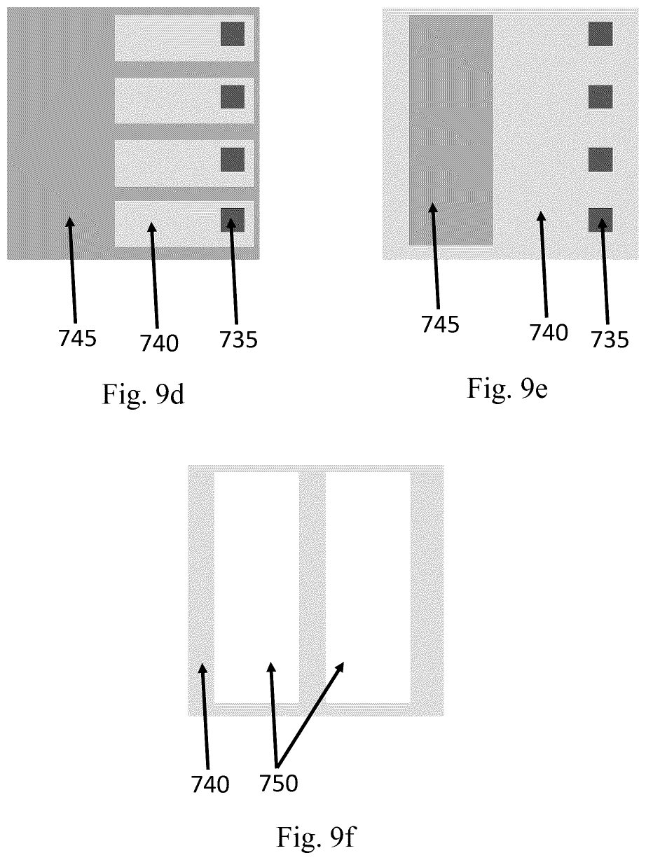

FIG. 9a-9f depicts various layers the light emitting device in a plan view according to embodiments of the invention. In particular, FIG. 9a shows the n surfaces 723 surrounded by the p surface 724. FIG. 9b shows the metal reflectors 735 spaced apart from each other. In the rings where the first metal reflectors 736 are spaced apart from the second metal reflector 737, DBR 730 is visible. FIGS. 9c-9e show portions of the metal reflectors 735, the second insulating layer 740, and the bonding structure 745. FIG. 9f shows the electrical contacts 750 spaced apart from each other so that the second insulating layer 740 is visible in between.

The disclosures provided in this specification are intended to illustrate but not necessarily to limit the described implementation. As used herein, the term “implementation” means an implementation that serves to illustrate by way of embodiments but not limitation. The techniques described in the preceding text and figures can be mixed and matched as circumstances demand to produce alternative implementations. It will be apparent to those of ordinary skill in the art that numerous variations, changes, and substitutions of the embodiments described above can be made without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. All such alternatives will be apparent to one skilled in the art in light of this disclosure and are intended to fall within the scope of the appended claims.

What is claimed is:

1. A light emitting device comprising:
a p-doped semiconductor, an active layer, and an n-doped semiconductor coupled to the p-doped semiconductor through the active layer;
one or more first transparent conductive oxide (TCO) layers directly contacting the p-doped semiconductor;
one or more first metal layers each directly contacting at least one of the one or more first TCO layers;
one or more second TCO layers comprising a contact region directly contacting the n-doped semiconductor and a second region extending outside the contact region, the one or more second TCO layers spaced apart from and overlapping the one or more first TCO layers in a vertical direction; and
one or more second metal layers each directly contacting at least one of the one or more second TCO layers.

2. The light emitting device of claim 1, wherein the one or more first metal layers comprise a same material as the one or more second metal layers.

3. The light emitting device of claim 1, wherein the one or more first metal layers do not overlap the one or more second metal layers.

4. The light emitting device of claim 1, wherein the one or more first metal layers are spaced apart from each of the one or more second metal layers.

5. The light emitting device of claim 4, wherein the one or more second metal layers directly contact the one or more second TCO layers above a surface of the n-doped semiconductor.

6. The light emitting device of claim 1, wherein the one or more second metal layers do not directly contact the n-doped semiconductor.

7. The light emitting device of claim 1, wherein the one or more second metal layers do not directly contact the p-doped semiconductor.

8. The light emitting device of claim 1, wherein the one or more second TCO layers comprises indium tin oxide.

9. The light emitting device of claim 1, further comprising a first insulating layer upon which the one or more second TCO layers is disposed.

10. The light emitting device of claim 9, wherein the first insulating layer extends over the p-doped semiconductor.

11. The light emitting device of claim 1, wherein the first insulating layer directly contacts a surface of the n-doped semiconductor.

12. The light emitting device of claim 1, further comprising a bonding structure on the one or more second metal layers.

13. The light emitting device of claim 12, wherein the bonding structure comprises a different material from the one or more second metal layers.

14. The light emitting device of claim 12, further comprising a second bonding structure on the one or more first metal layers.

15. The light emitting device of claim 12, further comprising an electrical contact on the bonding structure comprising a different material from the bonding structure.

16. The light emitting device of claim 12, wherein the one or more second metal layers have a higher reflectivity than the bonding structure.

17. The light emitting device of claim 1, further comprising a distributed bragg reflector (DBR) on the one or more second TCO layers.

18. The light emitting device of claim 17, wherein the DBR is disposed on the one or more first TCO layers.

19. The semiconductor structure of claim 1, wherein:
each of the one or more first metal layers directly contacts at least one of the one or more first TCO layers in a total contact area smaller than an entire area of that respective one or more first metal layers, and
each of the one or more second metal layer directly contacts at least one of the one or more second TCO layers in a total contact area smaller than an entire area of the one or more second metal layers.

20. The semiconductor structure of claim 19, wherein:
each of the one or more first metal layers directly contacts the one or more first TCO layers at multiple contact areas discontinuous from each other, and
each of the one or more second metal layers directly contacts the one or more second TCO layers at multiple contact areas discontinuous from each other.
